(19) United States
(12) Patent Application Publication
(10) Pub. No.: US 2025/0275369 A1
(43) Pub. Date: Aug. 28, 2025

(54) Display Device

(71) Applicant: LG Display Co., Ltd., Seoul (KR)

(72) Inventors: Dae-Hee Han, Paju-si (KR); Hun-Bae Im, Paju-si (KR); Yoon-Seok Lee, Paju-si (KR); Gyu-Hyeong Han, Paju-si (KR); Eon-Ho Cha, Paju-si (KR); Sang-Bin Shin, Paju-si (KR)

(21) Appl. No.: 18/818,015

(22) Filed: Aug. 28, 2024

(30) Foreign Application Priority Data
Feb. 27, 2024 (KR) 10-2024-0027923

(51) Int. Cl. H10K 59/122; H10K 59/80

(52) U.S. Cl. CPC H10K 59/122; H10K 59/8051

(57) ABSTRACT

A display device includes: a substrate including a display area having a plurality of subpixels and a non-display area that is adjacent to the display area; a first bank layer on the substrate, the first bank layer defining the plurality of subpixels; a transistor in each of the plurality of subpixels; a light emitting diode in each of the plurality of subpixels, the light emitting diode including a first electrode, an emitting layer on the first electrode and a second electrode on the emitting layer; and a field generating unit at both sides of the emitting layer, the field generating unit applying an electric field to the emitting layer, wherein the electric field is parallel to the substrate.

### CROSS REFERENCE TO RELATED APPLICATIONS

This application claims the priority of Republic of Korea Patent Application No. 10-2024-0027923, filed on Feb. 27, 2024, which is hereby incorporated by reference in its entirety.

### BACKGROUND

### Field

The present disclosure relates to a display device, and more particularly, to a display device where a luminous efficiency is improved.

### Discussion of Related Art

Recently, as a multimedia is progressed, an importance of a display device increases. As a result, a flat panel display such as a liquid crystal display (LCD), a plasma display panel (PDP) and an organic light emitting diode (OLED) display has been commercialized. Among various flat panel displays, an OLED display device has been widely used because of its high response speed, high luminance and wide viewing angle.

However, the OED display device has a disadvantage of a low light extraction efficiency. Further, when the OLED display device displays an image using red, green and blue light emitting diodes, the OLED display device has a luminous efficiency lower than about 10%.

### SUMMARY

Accordingly, the present disclosure is directed to a display device that substantially obviates one or more of the problems due to limitations and disadvantages of the related art.

An object of the present disclosure is to provide a display device where a luminous efficiency is improved.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate including a display area having a plurality of subpixels and a non-display area that is adjacent to the display area; a first bank layer on the substrate, the first bank layer defining the plurality of subpixels; a transistor in each of the plurality of subpixels; a light emitting diode in each of the plurality of subpixels, the light emitting diode including a first electrode, an emitting layer on the first electrode and a second electrode on the emitting layer; and a field generating unit at both sides of the emitting layer, the field generating unit applying an electric field to the emitting layer, wherein the electric field is parallel to the substrate.

In another embodiment, a display device includes: a substrate including a display area having a plurality of subpixels and a non-display area that is adjacent to the display area; a first bank layer on the substrate, the first bank layer defining the plurality of subpixels; a transistor in each of the plurality of subpixels; and a light emitting diode in each of the plurality of subpixels, the light emitting diode including a first electrode, an emitting layer on the first electrode and a second electrode on the emitting layer, wherein emitting molecules of the emitting layer are horizontally arranged and are parallel to the substrate.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIGS. 1A and 1B are views showing a random arrangement and a vertical arrangement, respectively, of emitting molecules of an emitting layer of a display device according one or more embodiments of the present disclosure;

FIG. 2 is a view showing a horizontal arrangement of emitting molecules of an emitting layer of a display device according to one or more embodiments of the present disclosure;

FIG. 3 is a view showing a display device according to a first embodiment of the present disclosure;

FIG. 4 is a view showing a subpixel of a display device according to one or more embodiments of the present disclosure;

FIG. 5 is a circuit diagram showing a subpixel of a display device according to the first embodiment of the present disclosure;

FIG. 6 is a cross-sectional view showing a display device according to the first embodiment of the present disclosure;

FIG. 7 is a cross-sectional view showing an emitting layer and a ferroelectric layer of a display device according to the first embodiment of the present disclosure;

FIGS. 8A to 8E are cross-sectional views showing a method of fabricating a display device according to the first embodiment of the present disclosure;

FIG. 9 is a cross-sectional view showing a display device according to a second embodiment of the present disclosure; and

FIG. 10 is a cross-sectional view showing a display device according to a third embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or embodiment of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit (i.e., driving circuit) for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or an oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

A luminous efficiency of an organic light emitting diode display device is determined by an internal quantum efficiency (IQE) and an external quantum efficiency (EQE). Since the internal quantum efficiency is determined by an emitting material and an internal structure of a display device, the internal quantum efficiency has been improved by development of the emitting material and change of the internal structure.

A light may not be escaped to be confined due to refractive index difference of an interior and an exterior of the display device or a light may be lost due to a surface plasmon polariton. As a result, the external quantum efficiency is determined by a light loss. To improve the external quantum efficiency, a research for minimizing the refractive index difference and an influence of a surface plasmon has been performed.

However, differently from the internal quantum efficiency, it has a limit to improve the external quantum efficiency. The present disclosure is suggested to improve the external quantum efficiency. Specifically, in the present disclosure, the external quantum efficiency is improved by solving a reduction factor of the external quantum efficiency different from the refractive index difference.

In the present disclosure, the luminous efficiency of the display device is improved by changing an arrangement of emitting molecules such as phosphorescent molecules or fluorescent molecules. The luminous efficiency of the display device is improved by changing the arrangement of the emitting molecules in an emitting layer instead of an external condition such as a structure or a refractive index of the display device.

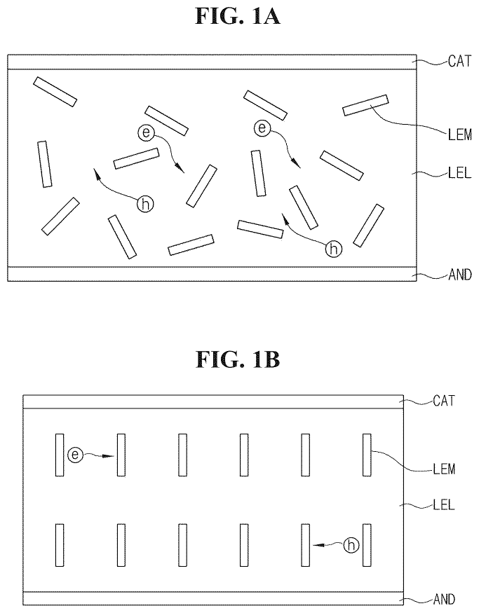

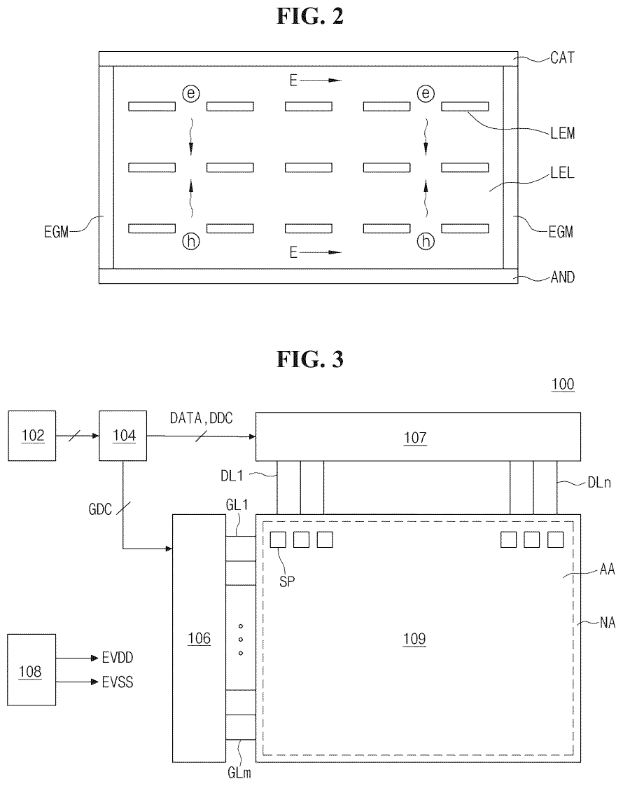

FIGS. 1A and 1B are views showing a random arrangement and a vertical arrangement, respectively, of emitting molecules of an emitting layer of a display device according to one or more embodiments of the present disclosure, and FIG. 2 is a view showing a horizontal arrangement of emitting molecules of an emitting layer of a display device according to one or more embodiments of the present disclosure.

In FIG. 1A, when an emitting layer LEL is formed by depositing an emitting material on a display device according to a comparison example without an external force, emitting molecules LEM are randomly arranged in the emitting layer LEL. The random arrangement of the emitting molecules LEM may reduce a luminous efficiency.

When a hole h and an electron e are injected into the emitting layer LEL from an anode AND having a relatively high work function and a cathode CAT having a relatively low work function in an organic light emitting diode display device, an exciton is generated in the emitting layer LEL. As the exciton decays, a light corresponding to an energy difference between a lowest unoccupied molecular orbital (LUMO) and a highest occupied molecular orbital (HOMO) of the emitting layer LEL is generated to display an image.

As a result, the luminous efficiency of the emitting layer LEL is changed according to a possibility of meeting of the hole h and the electron e. To increase the possibility of meeting of the hole h and the electron e, the hole h and the electron e should move toward the cathode CAT and the anode AND along a vertical direction where the cathode CAT and the anode AND are arranged.

A movement of the hole h and the electron e in an organic material is performed through a hopping between organic molecules. The hole h and the electron e move by a hopping between backbones of the emitting molecules LEM of an organic molecule.

When the emitting molecules LEM are randomly arranged in the emitting layer LEL, the hole h and the electron e do not move toward the cathode CAT and the anode AND along the vertical direction but move randomly. As a result, the possibility of meeting of the hole h and the electron e is reduced and the luminous efficiency is reduced.

In FIG. 1B, the emitting molecules LEM are arranged along the vertical direction where the cathode CAT and the anode AND are arranged. The emitting layer LEL are disposed between the cathode CAT and the anode AND, and the hole h and the electron e from the anode AND and the cathode CAT are transferred along the vertical direction.

The emitting molecules LEM may be arranged along the vertical direction due to increase of a temperature in a deposition step of the emitting layer LEL or subsequent steps. The emitting molecules LEM of an organic molecule are arranged due to an interaction with a substrate at a temperature equal to or lower than a glass transition temperature Tg. As the temperature increases near the glass transition temperature Tg, the emitting molecules LEM forms an aggregation for a thermodynamic stabilization instead of the interaction with the substrate. As the temperature increases, the emitting molecules LEM are arranged along the vertical direction for reducing a contact area of the backbone and the substrate. Further, since the emitting layer LEL consistently absorbs a heat generated in a process, the emitting molecules LEM are arranged along the vertical direction perpendicular to the substrate.

When the emitting molecules LEM are arranged along the vertical direction such that the backbone is parallel to the vertical direction, the hole h and the electron e move by a hopping between the backbones of the emitting molecules LEM. Since the hole h and the electron e move along a horizontal direction instead of the vertical direction, the possibility of meeting of the hole h and the electron e is further reduced and the luminous efficiency is further reduced as compared with the emitting layer LEL where the backbones of the emitting molecules LEM are randomly arranged.

FIG. 2 is a view showing an arrangement of emitting molecules of a display device according to a first embodiment of the present disclosure.

In FIG. 2, a display device according to an embodiment of the present disclosure includes a field generating unit (i.e., field generating patterns) EGM to generate an electric field E in an emitting layer LEL along a horizontal direction perpendicular to a vertical direction where an anode AND and a cathode CAT are arranged. Since an emitting molecule LEM in the emitting layer LEL is an organic molecule having a polarity, the emitting molecule LEM is arranged along the electric field E. Since the electric field E is generated along the horizontal direction perpendicular to the vertical direction, the emitting molecule LEM is arranged along the horizontal direction parallel to the anode AND and the cathode CAT.

Since the hole h released from the anode AND and the electron e released from the cathode CAT move between backbones of emitting molecules LEM by a hopping, the hole h and the electron e move toward the cathode CAT and the anode AND along the vertical direction. As a result, a possibility of meeting of the hole h and the electron e in the emitting layer LEL increases and a luminous efficiency increases. It is to be noted that although the embodiment shown in FIG. 2 is described as the emitting molecule LEM is horizontally arranged, the present disclosure is not limited thereto. For example, when the emitting molecule LEM is arranged to intersect with a direction from the anode AND to the cathode CAT, the luminous efficiency would increase compared with the vertical or random arrangement of the emitting molecule LEM.

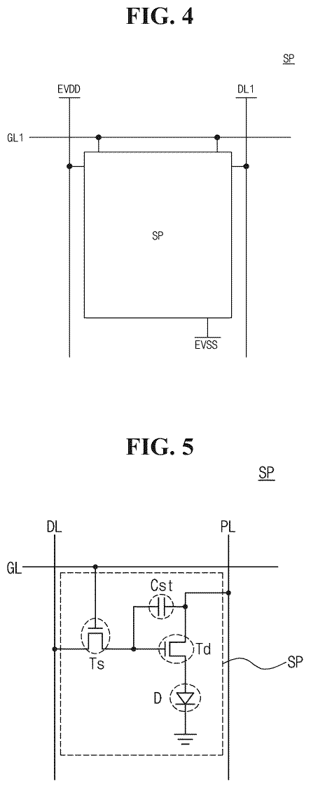

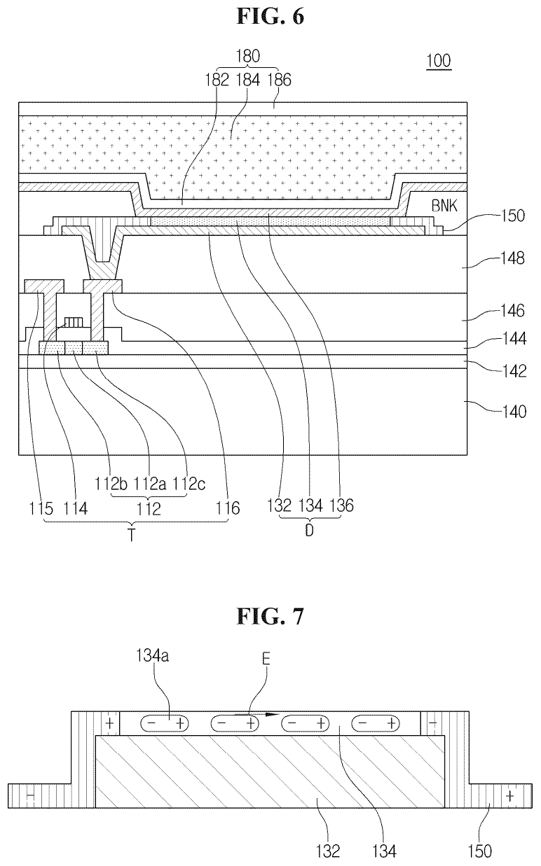

FIG. 3 is a view showing a display device according to the first embodiment of the present disclosure, and FIG. 4 is a view showing a subpixel of a display device according to the first embodiment of the present disclosure.

In FIG. 3, a display device 100 according to the first embodiment of the present disclosure includes an image processing circuit 102, a timing controlling circuit 104, a gate driving circuit 106, a data driving circuit 107, a power supplying circuit 108 and a display panel 109.

The image processing circuit 102 outputs a plurality of timing signals for various units as well as an image signal supplied from an exterior. For example, the plurality of timing signals may include a data enable signal, a vertical synchronization signal, a horizontal synchronization signal and a clock signal.

The timing controlling circuit 104 receives the image signal and the plurality of timing signals from the image processing circuit 102. The timing controlling circuit 104 generates an image data DATA, a gate control signal GDC and a data control signal DDC using the image signal and the plurality of timing signals. The timing controlling circuit 104 transmits the gate control signal GDC to the gate driving circuit 106 and transmits the image data and the data control signal DDC to the data driving circuit 107.

The gate driving circuit 106 generates a gate signal (a gate voltage, a scan signal) using the gate control signal GDC transmitted from the timing controlling circuit 104 and applies the gate signal to a plurality of gate lines GL1 to GLm of the display panel 109. Although the gate driving circuit 106 may be formed as an integrated circuit (IC), it is not limited thereto.

The gate driving circuit 106 may have a gate-in-panel (GIP) type where the gate driving circuit 106 is disposed on a substrate of the display panel 109.

The data driving circuit 107 generates a data signal (a data voltage) using the data control signal DDC and the image data DATA transmitted from the timing controlling circuit 104 and applies the data signal to a plurality of data lines DL1 to DLn of the display panel 109. The data driving circuit 107 samples and latches the image data DATA of a digital type to output the data signal of an analog type based on a gamma reference voltage. Although the data driving circuit 107 may be formed as an integrated circuit (IC), it is not limited thereto.

The power supplying circuit 108 outputs a high level voltage Vdd and a low level voltage Vss. The power supplying circuit 108 supplies the high level voltage Vdd to the display panel 109 through a first power line EVDD and supplies the low level voltage Vss to the display panel 109 through a second power line EVSS. In addition, the high level voltage Vdd and the low level voltage Vss of the power supplying part 108 may be supplied to the gate driving circuit 106 or the data driving circuit 107 for driving.

The display panel 109 displays an image using the gate signal of the gate driving circuit 106, the data signal of the data driving circuit 107 and the high level voltage Vdd and the low level voltage Vss of the power supplying circuit 108.

The display panel 109 includes a plurality of subpixels SP, a plurality of gate lines GL1 to GLm and a plurality of data lines DL1 to DLn. The plurality of subpixels SP may include red, green and blue subpixels SP or white, red, green and blue subpixels SP. The white, red, green and blue subpixels SP may have the same area as each other or may have a different area from each other.

In FIG. 4, a single subpixel SP may be connected to the gate line GL1, the data line DL1, the first power line EVDD and the second power line EVSS. A driving method as well as a number of a transistor and a capacitor of the subpixel SP may be determined according to a structure of a subpixel circuit. For example, the subpixel SP may have a structure of 2T1C including two transistors and one capacitor. In another embodiment, the subpixel SP may have a structure of one of 3T1C, 4T1C, 5T1C, 6T1C, 7T1C, 3T2C, 4T2C, 5T2C, 6T2C, 7T2C and 8T2C.

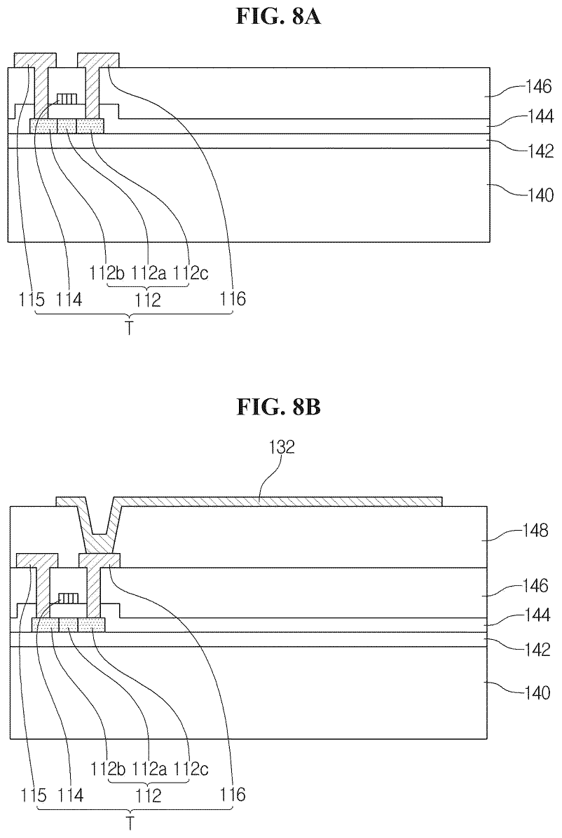

FIG. 5 is a circuit diagram showing a subpixel of a display device according to the first embodiment of the present disclosure.

In FIG. 5, the display device 100 includes the gate line GL, the data line DL and the power line PL crossing each other to define the subpixel SP. A switching transistor Ts, a driving transistor Td, a storage capacitor Cst and a light emitting diode D are disposed in the subpixel SP.

The switching transistor Ts is connected to the gate line GL and the data line DL. The driving transistor Td and the storage capacitor Cst are connected between the switching transistor Ts and the power line PL. The light emitting diode D is connected to the driving transistor Td.

When the switching transistor Ts is turned on according to the gate signal of the gate line GL, the data signal of the data line DL is applied to a gate electrode of the driving transistor Td and one capacitor electrode of the storage capacitor Cst through the switching transistor Ts.

Since the driving transistor Td is turned on according to the data signal, a current proportional to the data signal flows from the power line PL to the light emitting diode D through the driving transistor Td and the light emitting diode D emits a light of a luminance proportional to the current flowing through the driving transistor Td.

The storage capacitor Cst is charged up with a voltage proportional to the data signal to keep a voltage of the gate electrode of the driving transistor Td constant for one frame.

Although the subpixel SP includes two transistors Td and Td and one capacitor Cst in an embodiment of FIG. 5, the subpixel SP may include three or more transistors and two or more capacitors in another embodiment.

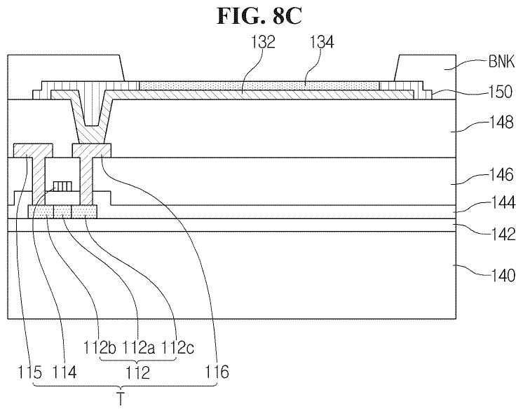

FIG. 6 is a cross-sectional view showing a display device according to the first embodiment of the present disclosure. Although the display device 100 includes a plurality of subpixels, only one subpixel is shown in FIG. 6 for illustration's convenience. Further, although a plurality of thin film transistors and a plurality of conductive lines are disposed in the subpixel, only one thin film transistor in a display area AA is shown in FIG. 6 for illustration's convenience.

In FIG. 6, a buffer layer 142 is disposed on a substrate 140. The substrate 140 may include a hard material such as a glass or a soft material such as a plastic material.

When the substrate 140 includes a plastic material, the substrate 140 may include at least one of polyimide (PI), polymethylmethacrylate (PMMA), polyethylene terephthalate (PET), polyether sulfone (PES) and polycarbonate (PC), and it is not limited thereto.

When the substrate 140 includes polyimide, the substrate 140 may include a plurality of polyimide layers. Further, an inorganic layer may be disposed between the polyimide layers, and it is not limited thereto.

The buffer layer 142 may be disposed on the entire substrate 140 to increase an adhesive strength between layers and the substrate 140 and to block an alkali ingredient released from the substrate 140. Further, the buffer layer 142 may delay diffusion of a moisture or an oxygen permeating the substrate 140.

The buffer layer 142 may have a single layer or a multiple layer of an inorganic insulating material such as silicon nitride (SiNx) and silicon oxide (SiOx). When the buffer layer 142 has a multiple layer, a layer of silicon nitride (SiNx) and a layer of and silicon oxide (SiOx) may be alternated with each other. The buffer layer 142 may be omitted based on a kind and a material of the substrate 140 and a structure and a type of the thin film transistor.

A thin film transistor T is disposed on the buffer layer 142. Although a driving thin film transistor among a plurality of thin film transistors in a display area AA is shown in FIG. 6, the subpixel may include the other thin film transistor such as a switching thin film transistor. Further, although the thin film transistor T has a top gate structure in FIG. 6, the thin film transistor T may have the other structure such as a bottom gate structure or a dual gate structure.

The thin film transistor T includes a semiconductor layer 112 on the buffer layer 142, a gate insulating layer 144 on the semiconductor layer 112, a gate electrode 114 on the gate insulating layer 144, an interlayer insulating layer 146 on the gate electrode 114 and source and drain electrodes 115 and 116 on the interlayer insulating layer 146.

The semiconductor layer 112 may include a polycrystalline semiconductor material. For example, the polycrystalline semiconductor material may include polycrystalline silicon, and it is not limited thereto.

The semiconductor layer 112 may include an oxide semiconductor material. For example, the oxide semiconductor material may include one of indium gallium zinc oxide (IGZO), indium zinc oxide (IZO), indium gallium tin oxide (IGTO) and indium gallium oxide (IGO), and it is not limited thereto. In another example, the oxide semiconductor material may include a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor material may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto. The semiconductor layer 112 has a channel region 112a of an intrinsic material at a central portion thereof and source and drain regions 112b and 112c of a doped material at both sides of the channel region 112a.

The gate insulating layer 144 may have a single layer or a multiple layer of an inorganic insulating material such as silicon nitride (SiNx) and silicon oxide (SiOx), and it is not limited thereto. The gate insulating layer 144 is an insulating layer for insulating the semiconductor layer 112 and the gate electrode 114 from each other.

The gate electrode 114 includes a metallic material. For example, the gate electrode 114 may have a single layer or a multiple layer of one of molybdenum (Mo), aluminum (Al), chromium (Cr), gold (Au), titanium (Ti), nickel (Ni), neodymium (Nd), copper (Cu) and an alloy thereof, and it is not limited thereto.

The interlayer insulating layer 146 may have a single layer or a multiple layer of an organic insulating material such as photoacryl or an inorganic insulating material such as silicon nitride (SiNx) and silicon oxide (SiOx). Further, the interlayer insulating layer 146 may have a multiple layer of an organic layer and an inorganic layer, and it is not limited thereto.

The source and drain electrodes 115 and 116 may have a single layer or a multiple layer of one of molybdenum (Mo), aluminum (Al), chromium (Cr), gold (Au), titanium (Ti), nickel (Ni), neodymium (Nd), copper (Cu) and an alloy thereof, and it is not limited thereto. The source and drain electrodes 115 and 116 may be connected to the source and drain regions 112b and 112c, respectively, of the semiconductor layer 112 through contact holes in the gate insulating layer 144 and the interlayer insulating layer 146.

Although not shown, a bottom shielding metal layer may include a material capable of blocking or reflecting light, and may be disposed on the substrate 140 under the semiconductor layer 112. The bottom shielding metal layer may minimize or at least reduce a back channel phenomenon generated due to charges trapped in the substrate 140 to prevent or at least reduce a residual image or deterioration of a transistor. The bottom shielding metal layer may have a single layer or a multiple layer of one of titanium (Ti), molybdenum (Mo) and an alloy thereof, and it is not limited thereto.

A planarizing layer 148 is disposed on the thin film transistor T over the entire substrate 140. The planarization layer 148 may be configured to protect the thin film transistor T and to planarize a step caused due to the thin film transistor T. The planarizing layer 148 may include an organic insulating material such as photoacryl, and it is not limited thereto. The planarizing layer 148 may have a multiple layer of an inorganic layer and an organic layer.

A light emitting diode D is disposed on the planarizing layer 148 in the display area AA. The light emitting diode D includes a first electrode 132, an emitting layer 134 and a second electrode 136.

The first electrode 132 may be an anode. The first electrode 132 is disposed on the planarizing layer 148 and is electrically connected to the drain electrode 116 of the thin film transistor T through a contact hole in the planarizing layer 148. The first electrode 132 may include at least one of silver (Ag), aluminum (Al), gold (Au), molybdenum (Mo), tungsten (W), chromium (Cr) and an alloy thereof. Alternatively, the first electrode 132 may include a transparent conductive material such as indium tin oxide (ITO) and indium zinc oxide (IZO).

When the display device 100 has a top emission type, the first electrode 132 may further include an opaque conductive material for using the first electrode 132 as a reflective layer. When the display device 100 has a bottom emission type, the first electrode 132 may include a transparent conductive material such as indium tin oxide (ITO) and indium zinc oxide (IZO).

A bank layer BNK is disposed in a boundary region of each subpixel. The bank layer BNK may be a kind of wall defining the subpixel. The bank layer BNK may prevent a mixture of lights of various colors emitted from adjacent subpixels.

The bank layer BNK may include at least one of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin and a photosensitive material including a black pigment, and it is not limited thereto.

Ferroelectric patterns 150 are disposed between the first electrode 132 and the bank layer BNK in the subpixel. The ferroelectric patterns 150 are a field generating unit EGM for arranging emitting molecules of the emitting layer 134 by applying an electric field to the emitting layer 134.

The ferroelectric patterns 150 may extend from the planarizing layer 148 toward a top edge surface of the first electrode 132 to wrap the first electrode 132 in a boundary area. Since the bank layer BNK covers the ferroelectric patterns 150, a portion of each ferroelectric pattern 150 on the top edge surface of the first electrode 132 extends from the bank layer BNK and the other portion of each ferroelectric pattern 150 is covered with the bank layer BNK.

The emitting layer 134 includes an organic emitting material. The emitting layer 134 is disposed on the top surface of the first electrode 132 exposed through the ferroelectric patterns 150 to extend toward a non-display area NA. The emitting layer 134 may have a thickness equal to or smaller than a thickness of each ferroelectric pattern 150 such that a side surface of each ferroelectric pattern 150 contacts a side surface of the emitting layer 134.

The ferroelectric patterns 150 may be formed through a deposition method. As a result, the ferroelectric patterns 150 may include a ferroelectric material having a Curie temperature higher than a deposition temperature of about 90° C. to about 100° C. For example, the ferroelectric patterns 150 may include a perovskite type (ABO₃) material such as barium titanate (BaTiO₃), lead titanate (PbTiO₃), potassium niobate (KNbO₃) and potassium tantalate (KTaO₃), and it is not limited thereto.

The emitting layer 134 may include a red emitting layer emitting a red colored light in a red subpixel, a green emitting layer emitting a green colored light in a green subpixel and a blue emitting layer emitting a blue colored light in a blue subpixel.

The emitting layer 134 may include an emitting material layer, an electron injecting layer injecting an electron, a hole injecting layer injecting a hole, an electron transporting layer transporting an electron, a hole blocking layer blocking a hole, an electron blocking layer blocking an electron and a hole transporting layer transporting a hole, and it is not limited thereto.

The second electrode 136 is disposed on the emitting layer 134. The second electrode 136 may have a single layer or a multiple layer of a metallic material or an alloy of metallic materials. Alternatively, the second electrode 136 may include a transparent conductive material such as indium tin oxide (ITO) and indium zinc oxide (IZO), and it is not limited thereto.

When the display device 100 has a top emission type, the second electrode 136 may include a half transmissive conductive material transmitting a light. For example, the second electrode 136 may include at least one of alloys of LiF/Al, CsF/Al, Mg:Ag, Ca/Ag, Ca:Ag, LiF/Mg:Ag, LiF/Ca/Ag and LiF/Ca:Ag.

When the display device 100 has a bottom emission type, the second electrode 136 may include an opaque conductive material for using the second electrode 136 as a reflective layer. For example, the second electrode 136 may include at least one of silver (Ag), aluminum (Al), gold (Au), molybdenum (Mo), tungsten (W), chromium (Cr) and an alloy thereof.

The light emitting diode D may have a tandem structure. The tandem structure may include a plurality of emitting layers and a charge generating layer between the plurality of emitting layers. The charge generating layer for adjusting a charge balance of the plurality of emitting layers may have a multiple layer including first and second charge generating layers. The charge generating layer may include a negative (N) type charge generating layer and a positive (P) type charge generating layer. For example, the charge generating layer may include an emitting layer doped with an alkali metal such as lithium (Li), sodium (Na), potassium (K) and cesium (Cs) or an alkali earth metal such as magnesium (Mg), strontium (Sr), barium (Ba) and radium (Ra), and it is not limited thereto.

An encapsulating layer 180 is disposed on the light emitting diode D to encapsulate the light emitting diode D. When the light emitting diode D is exposed to a moisture or an oxygen, a pixel shrinkage phenomenon where an emission area is reduced or deterioration of a dark spot in the emission area may occur. Further, a moisture or an oxygen may oxidize the electrode of a metallic material. The encapsulating layer 180 blocks permeation of a moisture or an oxygen from an exterior to prevent or at least reduce deterioration of the light emitting diode D and the electrodes.

Although the encapsulating layer 180 has a triple layer of first, second and third encapsulating layers 182, 184 and 186 in a first embodiment, the encapsulating layer 180 may have a double layer or a quadruple layer in another embodiment.

The first and third encapsulating layer 182 and 186 may have a single layer or a multiple layer of an inorganic material such as silicon oxide (SiOx), silicon oxynitride (SiON) and silicon nitride (SiNx). The first and third encapsulating layer 182 and 186 may further include an organic material between the inorganic materials, and it is not limited thereto. The second encapsulating layer 184 may include epoxy resin.

Although not shown, the display device 100 may include a touch unit (e.g., a touch circuit). The touch circuit may be disposed in the display area to sense a touch input. For example, the touch circuit may sense an external touch information using a finger of a user or a touch pen.

In the display device 100 according to a first embodiment of the present disclosure, since the ferroelectric patterns 150 are disposed at opposite sides, respectively, of the emitting layer 134, an electric field is generated between the ferroelectric patterns 150 and emitting molecules are horizontally arranged along the electric field.

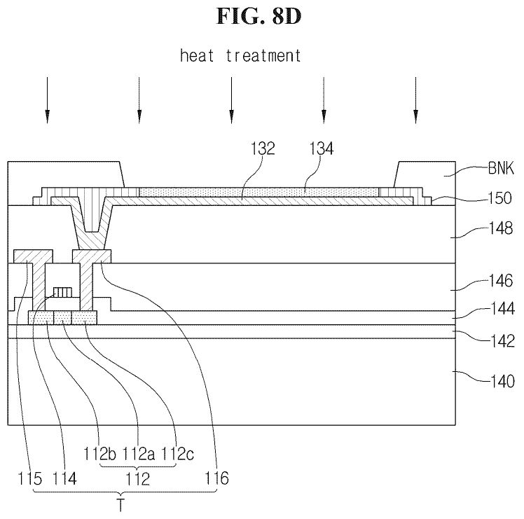

FIG. 7 is a cross-sectional view showing an emitting layer and a ferroelectric layer of a display device according to the first embodiment of the present disclosure.

In FIG. 7, the ferroelectric layer or the ferroelectric pattern 150 is disposed at opposite sides of the emitting layer 134. Since the ferroelectric layer or the ferroelectric pattern 150 of a ferroelectric material is polarized along a horizontal direction in a temperature lower than a Curie temperature, an electric field E is generated between portions of the ferroelectric layer or the ferroelectric pattern 150 at both sides of the emitting layer 134 to be applied to the emitting layer 134.

Since emitting molecules 134a of the emitting layer 134 are a polar molecule, the emitting molecules 134a are arranged along the electric field E applied to the emitting layer 134. As a result, the emitting molecules 134a are horizontally arranged to be parallel to a surface of the substrate 140.

When the emitting molecules 134a are horizontally arranged as in FIG. 2, a hole h emitted from the first electrode 132 moves toward the second electrode 136 along a vertical direction and an electron e emitted from the second electrode 136 moves toward the first electrode 132 along the vertical direction. As a result, a possibility of meeting of the hole h and the electron e increases, and an internal quantum efficiency of the emitting layer 134 and a luminous efficiency of the display device 100 are improved.

A method of fabricating the display device 100 will be illustrated hereinafter.

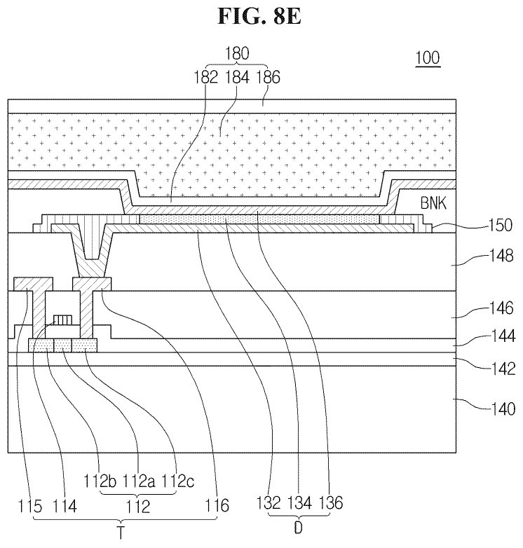

FIGS. 8A to 8E are cross-sectional views showing a method of fabricating a display device according to the first embodiment of the present disclosure.

In FIG. 8A, the buffer layer 142 is formed on the entire substrate 140. The substrate 140 may include a hard material such as a glass or a plastic material such as polyimide (PI), polymethylmethacrylate (PMMA), polyethylene terephthalate (PET), polyether sulfone (PES) and polycarbonate (PC). The buffer layer 142 may have a single layer or a multiple layer of an inorganic insulating material such as silicon nitride (SiNx) and silicon oxide (SiOx).

Next, after a semiconductor material layer of a polycrystalline semiconductor material such as polycrystalline silicon or an oxide semiconductor material such as indium gallium zinc oxide (IGZO), indium zinc oxide (IZO), indium gallium tin oxide (IGTO) and indium gallium oxide (IGO) is formed on the buffer layer 142, the semiconductor layer 112 is formed on the buffer layer 142 in each subpixel SP by patterning the semiconductor material layer. Next, the channel region 112a, the source region 112b and the drain region 112c are formed in the semiconductor layer 112 by doping side portions of the semiconductor layer 112 with an impurity.

Next, the gate insulating layer 144 of an inorganic insulating material such as silicon nitride (SiNx) and silicon oxide (SiOx) is formed on the semiconductor layer 112 over the entire substrate 140. Next, after a metallic material layer of a metallic material such as molybdenum (Mo), aluminum (Al), chromium (Cr), gold (Au), titanium (Ti), nickel (Ni), neodymium (Nd) and copper (Cu) is formed on the gate insulating layer 144, the gate electrode 114 is formed on the gate insulating layer 144 in each subpixel SP by patterning the metallic material layer. Next, after the interlayer insulating layer 146 of an organic insulating material such as photoacryl or an inorganic insulating material such as silicon nitride (SiNx) and silicon oxide (SiOx) is formed on the gate electrode 114 over the entire substrate 140, contact holes exposing the source and drain regions 112b and 112c are formed in the interlayer insulating layer 146 and the gate insulating layer 144 by patterning.

Next, after a metallic material layer of a metallic material such as molybdenum (Mo), aluminum (Al), chromium (Cr), gold (Au), titanium (Ti), nickel (Ni), neodymium (Nd) and copper (Cu) is formed on the interlayer insulating layer 146, the source and drain electrodes 115 and 116 contacting the source and drain regions 112b and 112c, respectively, of the semiconductor layer 112 are formed on the interlayer insulating layer 146 in each subpixel SP by patterning the metallic material layer. The semiconductor layer 112, the gate insulating layer 144, the gate electrode 114, the source electrode 115 and the drain electrode 116 constitute the thin film transistor T.

In FIG. 8B, after the planarizing layer 148 of an organic insulating material such as photoacryl is formed on the thin film transistor T over the entire substrate 140, a contact hole exposing the drain electrode 116 is formed in the planarizing layer 148 by patterning.

Next, after a metallic material layer of a metallic material such as silver (Ag), aluminum (Al), gold (Au), molybdenum (Mo), tungsten (W) and chromium (Cr) or a transparent conductive material such as indium tin oxide (ITO) and indium zinc oxide (IZO) is formed on the planarizing layer 148, the first electrode 132 contacting the drain electrode 116 of the thin film transistor T is formed on the planarizing layer 148 by patterning the metallic material layer.

In FIG. 8C, after a ferroelectric material layer of a ferroelectric material of a perovskite type (ABO₃) such as barium titanate (BaTiO₃), lead titanate (PbTiO₃), potassium niobate (KNbO₃) and potassium tantalate (KTaO₃) is formed on the first electrode 132 over the entire substrate 140, the ferroelectric patterns 150 are formed on both edge portions of the first electrode 132 by patterning the ferroelectric material layer.

Next, after an insulating material layer of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin or a photosensitive material including a black pigment is formed on the ferroelectric material 150 over the entire substrate 140, the bank layer BNK is formed on the ferroelectric patterns 150 and the planarizing layer 148 by patterning the insulating material layer.

The bank layer BNK is disposed between the adjacent subpixels SP, and a portion of each ferroelectric pattern 150 and a portion of the first electrode 132 are exposed through the bank layer BNK.

Next, the emitting layer 134 is formed on the first electrode 132 by depositing and patterning an emitting material.

The emitting layer 134 is disposed between the ferroelectric patterns 150 such that side surfaces of the emitting layer 134 contact side surfaces of the ferroelectric patterns 150. The ferroelectric patterns 150 and the emitting layer 134 may have the same thickness as each other to have a flat top surface or may have different thickness from each other to have a relatively small step difference on a top surface.

Since the emitting layer 134 is disposed between the ferroelectric patterns 150, an electric field generated between the opposite ferroelectric patterns 150 is applied to the emitting layer 134. Since the emitting molecules that are randomly or vertically arranged in the emitting layer 134 move along the electric field, the emitting molecules are horizontally arranged parallel to the surface of the first electrode 132.

Although the emitting layer 134 is formed after forming the bank layer BNK in a first embodiment, the bank layer BNK is formed after forming the emitting layer 134 in another embodiment.

In FIG. 8D, a heat treatment (aging) is performed to the substrate 140 having the ferroelectric patterns 150 with a temperature higher than a Curie temperature of the ferroelectric patterns 150. For example, when the ferroelectric patterns 150 includes a perovskite type (ABO₃) ferroelectric material such as barium titanate (BaTiO₃), lead titanate (PbTiO₃), potassium niobate (KNbO₃) and potassium tantalate (KTaO₃), the heat treatment may be performed in a temperature higher than about 90° C. to about 100° C.

Since the ferroelectric patterns 150 is treated by a heat of a temperature higher than a Curie temperature, a polarity state of the ferroelectric material of the ferroelectric patterns 150 is removed. As a result, a trap of an electron or a leakage of a current between the adjacent subpixels due to the polarity is prevented or at least reduced.

In FIG. 8E, after a metallic material layer of a metallic material or a transparent conductive material is formed on the emitting layer 134 over the entire substrate 140, the second electrode 136 is formed on the emitting layer 134, the ferroelectric patterns 150 and top and side surfaces of the bank layer BNK by patterning the metallic material layer. The first electrode 132, the emitting layer 134 and the second electrode 136 constitute the light emitting diode D.

Next, the encapsulating layer 180 including the first, second and third encapsulating layers 182, 184 and 186 is formed on the light emitting diode D over the entire substrate 140 by sequentially depositing an inorganic material, an organic material and an inorganic material.

In the display device 100 according to a first embodiment of the present disclosure, since the ferroelectric patterns 150 having a polarity state are disposed at both sides of the emitting layer 134, the emitting molecules are horizontally arranged in a step of forming the emitting layer 134. As a result, an internal quantum efficiency of the emitting layer 134 is improved. Since the ferroelectric patterns 150 are treated with a heat of a temperature higher than a Curie temperature after a step of forming the emitting layer 134, the polarity state of the ferroelectric molecules of the ferroelectric patterns 150 is removed. As a result, a trap of an electron or a leakage of a current between the adjacent subpixels due to the polarity is prevented or at least reduced.

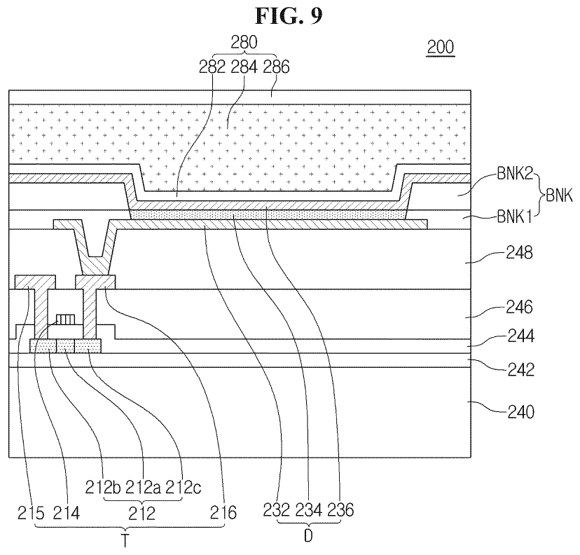

FIG. 9 is a cross-sectional view showing a display device according to a second embodiment of the present disclosure. Illustration on the same part as a first embodiment may be omitted.

In FIG. 9, a thin film transistor T and a light emitting diode D are disposed on a substrate 240.

The thin film transistor T includes a semiconductor layer 212 on a buffer layer 242, a gate insulating layer 244 on the semiconductor layer 212, a gate electrode 214 on the gate insulating layer 244, an interlayer insulating layer 246 on the gate electrode 214 and source and drain electrodes 215 and 216 on the interlayer insulating layer 246.

A planarizing layer 248 is disposed on the thin film transistor T, and a bank layer BNK is disposed in a boundary region of each subpixel. The light emitting diode D includes a first electrode 232, an emitting layer 234 and a second electrode 236.

The bank layer BNK includes first bank patterns BNK1 on the planarizing layer 248 and a second bank layer BNK2 on the first bank patterns BNK1. The first bank patterns BNK1 includes a perovskite type (ABO₃) ferroelectric material such as barium titanate (BaTiO₃), lead titanate (PbTiO₃), potassium niobate (KNbO₃) and potassium tantalate (KTaO₃), or a polymer having a polarity, so as to apply an electric field to the emitting layer 234. The first bank patterns BNK1 may also be referred to as first bank layers.

The first bank patterns BNK1 may have the same thickness as the emitting layer 234 such that side surfaces of the first bank patterns BNK1 contact side surfaces of the emitting layer 234 to apply an electric field to the entire emitting layer 234. Alternatively, the first bank patterns BNK1 may have a greater thickness than the emitting layer 234. The emitting molecules having a polarity are horizontally arranged along the electric field to be parallel to the surface of the substrate 240.

The second bank layer BNK2 may include at least one of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin and a photosensitive material including a black pigment, and it is not limited thereto.

An encapsulating layer 280 including a first encapsulating layer 282 of an inorganic material, a second encapsulating layer 284 of an organic material and a third encapsulating layer 286 of an inorganic material is disposed on the light emitting diode D.

In the display device 200 according to a second embodiment of the present disclosure, since a portion of the bank layer BNK is formed of the ferroelectric material and the electric field is generated between the bank layer BNK, the emitting molecules are horizontally arranged to be parallel to the surface of the substrate 240 and the luminous efficiency of the display device 200 is improved

In another embodiment, the entire bank layer BNK may be formed of the ferroelectric material to generate an electric field, and the emitting molecules of the emitting layer 234 may be horizontally arranged to be parallel to the surface of the substrate 240.

The ferroelectric material of the bank layer BNK is treated with a heat of a temperature higher than a Curie temperature after the emitting molecules are arranged, and the polarity state of the ferroelectric materials are removed.

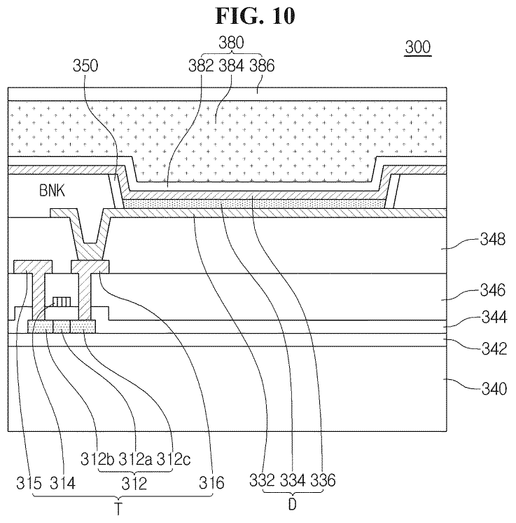

FIG. 10 is a cross-sectional view showing a display device according to a third embodiment of the present disclosure. Illustration on the same part as first and second embodiments may be omitted.

In FIG. 10, ferroelectric patterns 350 for applying an electric field to an emitting layer 334 are disposed on side surfaces of a bank layer BNK contacting the emitting layer 334.

In the display device 300 according to a third embodiment of the present disclosure, since the electric field is generated between the ferroelectric patterns 350 of a ferroelectric material, the emitting molecules of the emitting layer 334 are horizontally arranged to be parallel to the surface of the substrate 340 and the luminous efficiency of the display device 300 is improved

Although the ferroelectric patterns 350 are disposed on the side surfaces of the bank layer BNK in a third embodiment, the ferroelectric patterns 350 may be disposed on the side and top surfaces of the bank layer BNK in another embodiment. It is to be noted that the embodiments shown in FIGS. 6 to 10 are provided by way of example only, and the present disclosure is not limited thereto. For example, as long as the emitting molecules of the emitting layer are arranged uniformly to at least intersect with the vertical direction, the structure of the pixels in the display devices shown in FIGS. 6 to 10 may be variously changed.

Consequently, in the display device according to the present disclosure, since the electric field generated by the ferroelectric patterns is applied to the emitting layer, the emitting molecules of the emitting layer are horizontally arranged to be parallel to the surface of the substrate. Since the hole and the electron vertically move, the internal quantum efficiency of the emitting layer and the luminous efficiency of the display device are improved.

Further, since the luminous efficiency is improved, the low power consumption is obtained.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display device, comprising:
a substrate including a display area having a plurality of subpixels;
a first bank layer on the substrate, the first bank layer defining the plurality of subpixels;
a light emitting diode in each of the plurality of subpixels, the light emitting diode including a first electrode, an emitting layer on the first electrode and a second electrode on the emitting layer; and
a field generating unit at both sides of the emitting layer, the field generating unit applying an electric field to the emitting layer, wherein the electric field is parallel to the substrate.

2. The display device of claim 1, wherein the field generating unit includes a ferroelectric material.

3. The display device of claim 2, wherein the ferroelectric material is of a perovskite type (ABO₃).

4. The display device of claim 3, wherein the ferroelectric material includes one of a barium titanate (BaTiO₃), a lead titanate (PbTiO₃), a potassium niobate (KNbO₃), and a potassium tantalate (KTaO₃).

5. The display device of claim 2, further comprising:
a transistor in each of the plurality of subpixels; and
a planarizing layer covering the transistor,
wherein the emitting layer is on the planarizing layer.

6. The display device of claim 5, wherein the field generating unit includes ferroelectric patterns on the planarizing layer,
wherein the ferroelectric patterns extend to the first electrode, and
wherein the emitting layer is on the first electrode and between the ferroelectric patterns.

7. The display device of claim 6, wherein the ferroelectric patterns extend from the planarizing layer toward a top edge surface of the first electrode to wrap the first electrode in a boundary area.

8. The display device of claim 6, wherein a thickness of the ferroelectric patterns is a same as a thickness of the emitting layer.

9. The display device of claim 2, wherein the field generating unit includes a second bank layer under the first bank layer.

10. The display device of claim 2, wherein the field generating unit includes ferroelectric patterns on at least one side surface of the first bank layer.

11. The display device of claim 2, wherein the field generating unit is treated with a heat having a temperature that is higher than a Curie temperature.

12. The display device of claim 2, wherein the field generating unit is subject to a heat treatment such that a polarity state of the ferroelectric material is removed.

13. The display device of claim 1, wherein a side surface of the field generating unit is in contact with a side surface of the emitting layer.

14. The display device of claim 1, wherein the second electrode is in contact with the field generating unit.

15. A display device, comprising:
a substrate including a display area having a plurality of subpixels;
a first bank layer on the substrate, the first bank layer defining the plurality of subpixels; and
a light emitting diode in each of the plurality of subpixels, the light emitting diode including a first electrode, an emitting layer on the first electrode and a second electrode on the emitting layer,
wherein emitting molecules of the emitting layer are horizontally arranged and are parallel to the substrate.

16. The display device of claim 15, wherein the emitting molecules are arranged by an electric field that is applied to the emitting layer.

17. The display device of claim 16, further comprising:
a field generating unit at both sides of the emitting layer,
wherein the field generating unit includes a polymer having a polarity, and
wherein the polymer applies an electric field to the emitting layer.

18. The display device of claim 17, wherein the polymer is treated with a heat having a temperature higher than a Curie temperature.

19. The display device of claim 17, wherein the polymer is subject to a heat treatment such that a polarity state of the polymer is removed.

20. A display device, comprising:
a substrate having a display area with a plurality of subpixels;
a first bank layer on the substrate, the first bank layer defining the plurality of subpixels; and
a light emitting diode in each of the plurality of subpixels, the light emitting diode including a first electrode, an emitting layer on the first electrode and a second electrode on the emitting layer,
wherein emitting molecules of the emitting layer are arranged to intersect with a direction from the first electrode to the second electrode.
